(19) United States
(12) Patent Application Publication
(10) Pub. No.: US 2026/0096176 A1
(43) Pub. Date: Apr. 2, 2026

(54) Air Gap for Capacitance Reduction in Amplifier Devices

(71) Applicant: Newport Fab, LLC dba Tower Semiconductor Newport Beach, Newport Beach, CA (US)

(72) Inventors: Allan K. Calvo, Tustin, CA (US); Roda Kanawati, Irvine, CA (US); Kurt Moen, Tustin, CA (US)

(21) Appl. No.: 18/903,888

(22) Filed: Oct. 1, 2024

(51) Int. Cl. H01L 29/417; H01L 27/12; H01L 29/78; H03F 3/19

(52) U.S. Cl. CPC H10D 64/258; H10D 30/637; H10D 86/201; H03F 3/19; H03F 2200/451

(57) ABSTRACT

A semiconductor structure includes a first transistor and a second transistor. The first transistor includes first drain and source contacts in a pre-metal dielectric, a first gap in the pre-metal dielectric over an active area and offset from a first gate towards the first drain contact, and a first gap dielectric in the first gap. The second transistor includes second drain and source contacts in a pre-metal dielectric, a second gap in the pre-metal dielectric between the second drain and source contacts, and a second gap dielectric in the second gap. The first and second gap dielectrics have a dielectric constant less than that of the pre-metal dielectric. The gap dielectrics can include air. The first and/or second transistors can also include gaps over isolation areas between respective gates and respective drain and/or source contacts. The semiconductor structure can be an amplifier.

### BACKGROUND

Radio frequency (RF) amplifiers are commonly utilized in wireless communication devices (e.g., smart phones) to convert a low-power RF signal to a higher-power signal, for example between the device's processing circuitry and the device's antenna. Transistors, such as field effect transistors (FETs), are key components of RF amplifiers.

However, conductive materials and dielectric materials used in transistors often contribute to parasitic capacitances associated with RF frequencies. Further, these parasitic capacitances are augmented in RF amplifiers due to a phenomenon known as the Miller effect. The Miller effect can disrupt impedance matching and feedback networks, and impacts the stability of the RF amplifier. It can also reduce the RF amplifier's bandwidth. Fabricating transistors without significant RF performance tradeoffs becomes difficult and complex.

Thus, there is a need in the art for transistors with reduced capacitances that accommodate different requirements in an RF amplifier.

### SUMMARY

The present disclosure is directed to implementing air gaps for capacitance reduction in amplifier devices, substantially as shown in and/or described in connection with at least one of the figures, and as set forth in the claims.

### BRIEF DESCRIPTION OF THE DRAWINGS

FIG. 1A illustrates an amplifier according to one implementation of the present application.

FIG. 1B illustrates a portion of an amplifier circuit corresponding to the amplifier of FIG. 1A and employing a transistor according to one implementation of the present application.

FIG. 2A illustrates a top view of a portion of a transistor according to one implementation of the present application.

FIG. 2B illustrates a cross-sectional view of a portion of a transistor in FIG. 2A according to one implementation of the present application.

FIG. 2C illustrates a cross-sectional view of a portion of a transistor in FIG. 2A according to one implementation of the present application.

FIG. 3A illustrates a top view of a portion of a transistor according to one implementation of the present application.

FIG. 3B illustrates a cross-sectional view of a portion of a transistor in FIG. 3A according to one implementation of the present application.

### DETAILED DESCRIPTION

The following description contains specific information pertaining to implementations in the present disclosure. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions. Further, in the present application the terms “connected” to/with or “coupled” to/with may be used interchangeably to have the same or similar meaning, and each term may mean direct or indirect connection.

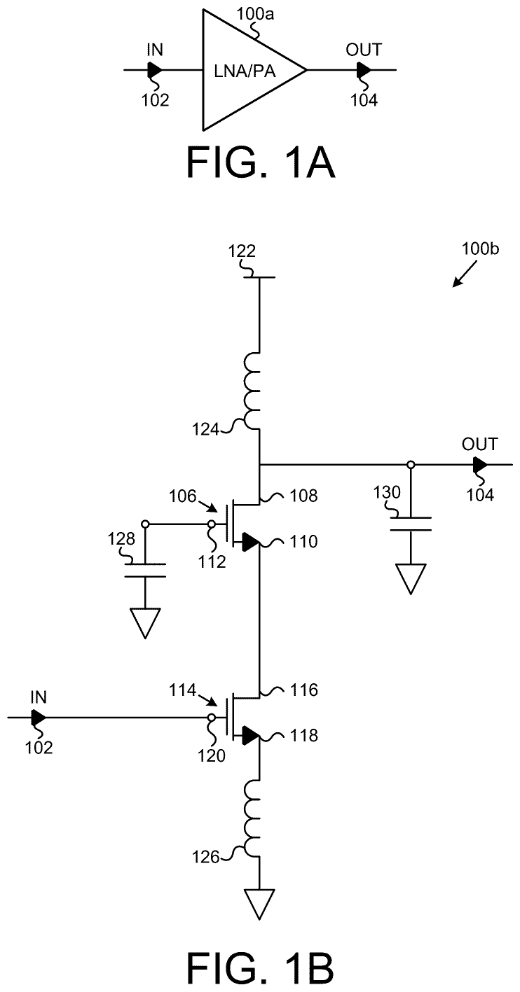

FIG. 1A illustrates an amplifier according to one implementation of the present application. Amplifier 100a amplifies electrical signals received at input 102 and provides the amplified electrical signals to output 104. FIG. 1B illustrates a portion of an amplifier circuit corresponding to the amplifier of FIG. 1A and employing a transistor according to one implementation of the present application.

As shown in FIG. 1B, amplifier circuit 100b includes input 102, output 104, transistor 106 including drain 108, source 110, and gate 112, transistor 114 including drain 116, source 118, and gate 120, supply voltage 122, drain inductance 124, source inductance 126, gate capacitance 128, and load capacitance 130. Amplifier circuit 100b, input 102, and output 104 in FIG. 10B generally correspond to amplifier 100a, input 102, and output 104 in FIG. 1A.

Input 102 is coupled to gate 120 of transistor 114. Source 118 of transistor 114 is coupled to source inductance 126, which is coupled to ground. Drain 116 of transistor 114 is coupled to source 110 of transistor 106. Gate 112 of transistor 106 is coupled to gate capacitance 128, which may represent a biasing voltage for transistor 106. Drain 108 of transistor 106 is coupled to drain inductance 124, which is coupled to supply voltage 122. Drain 108 of transistor 106 is also coupled to output 104 and to load capacitance 130, which is coupled to ground.

Amplifier circuit 100b employs transistors 106 and 114 coupled in cascode to achieve amplification. Transistor 114 is a lower transistor of the cascode, and is preferably configured to optimize gain and minimize noise, and may be any SOI transistor known in the art. Transistor 106 is an upper transistor of the cascode, and is preferably configured to provide control over body effect and the linearity of the amplification. In one implementation, amplifier 100a or amplifier circuit 100b utilizing transistors 106 and 114 according to the present application can be a low-noise amplifier (LNA). In another implementation, transistors 106 and 114 can be utilized in a power amplifier (PA), which may utilize a similar circuit to amplifier circuit 100b, albeit having multiple stages. In amplifier circuit 100b, Miller capacitance occurring between input 102 and output 104 can negatively impact performance.

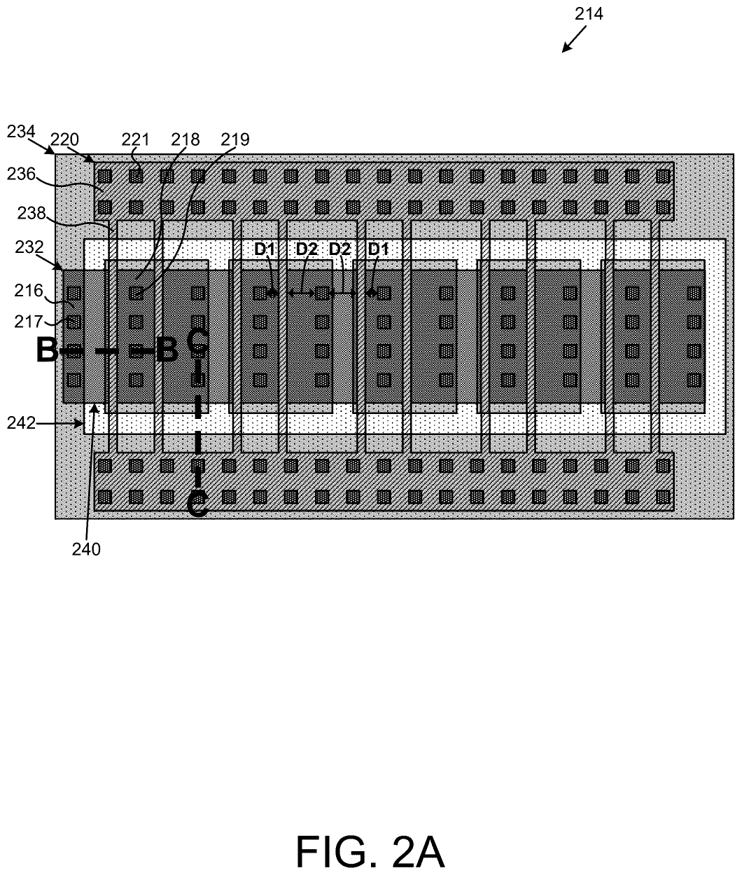

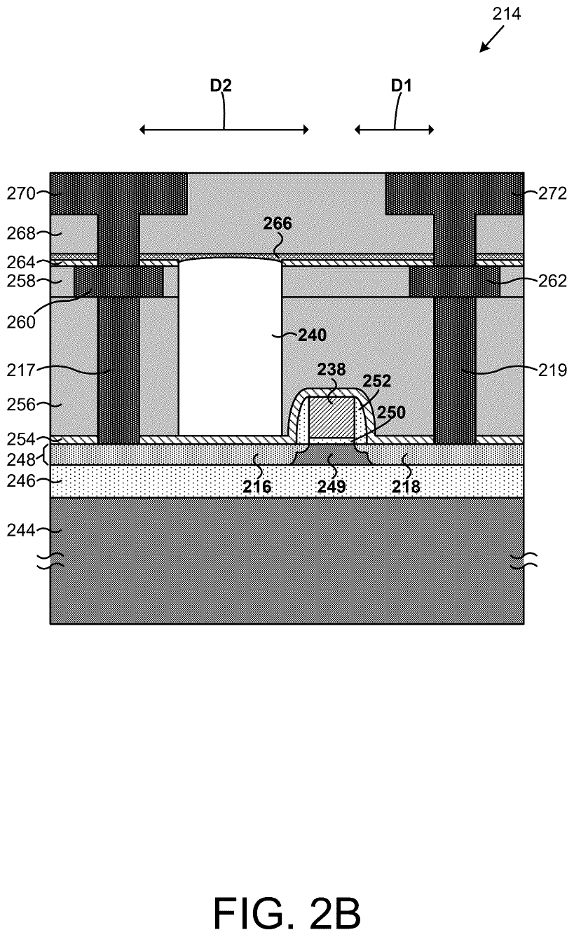

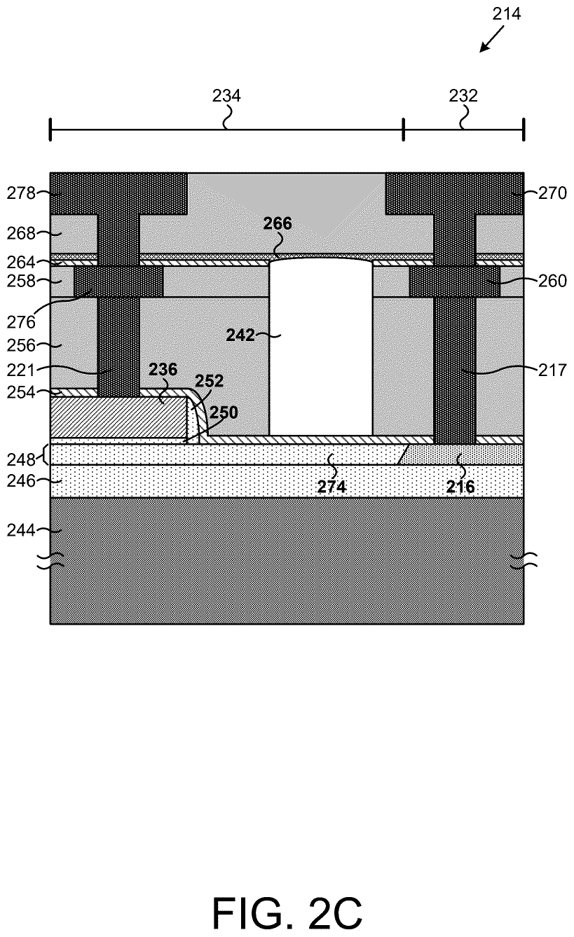

FIG. 2A illustrates a top view of a portion of a transistor according to one implementation of the present application. As shown in FIG. 2A, transistor 214 includes drains 216, drain contacts 217, sources 218, source contacts 219, gate 220, gate contact pads 236, gate fingers 238, gate contacts 221, active area 232, isolation area 234, gaps 240, and gaps 242. Transistor 214, drains 216, sources 218, and gate 220 in FIG. 2A generally correspond to transistor 114, drain 116, source 118, and gate 120 in FIG. 1B. In other words, transistor 214 in FIG. 2A can be the lower transistor 114 of the cascode in amplifier circuit 110b in FIG. 1B. Certain features may be omitted or seen-through for simplicity.

Active area 232 of transistor 214 includes drains 216 and sources 218. Active area 232 also includes bodies (not shown) under gate fingers 238. In the present implementation, active area 232 is substantially rectangular. Isolation area 234 is situated around active area 232 and isolates active area 232. For example, isolation area 234 can isolate active area 232 of transistor from adjacent devices (not shown). Isolation area 234 can include, shallow trench isolation (STI), local oxidation of silicon (LOCOS), or any other isolation technique. In other implementations, active area 232 can include additional features, such as a body contact area.

Drain contacts 217 and source contacts 219 are situated over and contact drains 216 and sources 218 respectively. Gate contacts 221 are situated over and contact gate contact pads 236 of gate 220. In one implementation, drain contacts 217, source contacts 219, and gate contacts 221 comprise tungsten (W). In various implementations, transistor 214 can have more or fewer contacts than shown in FIG. 2A.

Gate 220 includes gate contact pads 236 and gate fingers 238. Gate pads 236 are situated over isolation area 234. Gate contact pads 236 are segments of gate 220 at terminal portions of gate fingers 238. Gate contact pads 236 are wider than gate fingers 238. Gate contact pads 236 facilitate connecting electrical connectors, such as gate contacts 221, to gate fingers 238. In the present implementation, gate contact pads 236 are substantially rectangular and parallel to active area 232. In one implementation, gate 220 comprises polycrystalline silicon (polysilicon).

Gate fingers 238 are narrow elongated segments of gate 220. Gate fingers extend from over isolation area 234 to over active area 232. Terminal portions of gate fingers 238 connect with gate contact pads 236. Main portions of gate fingers 238 are situated between drains 216 and sources 218. In the present implementation, gate fingers 238 are substantially perpendicular to active area 232 and gate contact pads 236. Gate fingers 238 can be used to induce a conductive channel in active area 232.

In present implementation, gate 220 is a digitated structure where multiple gate fingers 238 are connected by gate contact pads 236 and perform as a single gate 220.

Gate 220 includes ten gate fingers 238 and two gate contact pads 236. Transistors in amplifier applications can have a low number of gate fingers, for example, less than twenty gate fingers. A greater number of gate fingers can be difficult to bias, and may also complicate manufacturing when gap 242 is utilized. In various implementations, transistor 214 can have more or fewer gate fingers 238 and/or gate contact pads 236 than shown in FIG. 2A. For example, a single gate finger may be utilized without any gate contact pads. However, because transistor 214 includes gate contact pads 236, gate contacts 221 are not situated over active area 232. Gate contacts 221 are further from drain contacts 217 and source contacts 219, thereby reducing capacitive coupling.

Notably, in transistor 214, drains 216 and sources 218 are not symmetrical with respect to gate fingers 238. Drains 216 are longer than sources 218. As a result, drain contacts 217 are situated further from gate fingers 238 than source contacts 219. That is, a first distance D1 from a gate finger 238 to its nearest source contact 219 is significantly less than a second distance D2 from the gate finger 238 to its nearest drain contact 217. As a result, capacitance between gate finger 238 of gate 220 and drain contact s 217 is reduced. In one implementation, distance D2 is fifty percent greater than distance D1.

Transistor 214 includes gaps 240 and 242 in a pre-metal dielectric. The top view shown in FIG. 2A illustrates objects seen through the pre-metal dielectric layer with darker shading, and illustrates gaps 240 and 242 as grid-like breaks in the shading. Gaps 240 are situated overactive area 232 and offset from gate fingers 238 towards drain contacts 217. In the present implementation, gaps 240 are substantially rectangular and parallel to gate fingers 238. Gaps 242 are situated over isolation area 234, between gate contact pad 236 and drain contacts 217. In the present implementation, gaps 242 are substantially rectangular and parallel to gate contact pads 236.

Gap dielectrics are situated in gaps 240 and 242. The gap dielectrics have a lower dielectric constant than the pre-metal dielectric. For example, if the pre-metal dielectric has a dielectric constant of approximately 3.9, gap dielectrics in gaps 240 and 242 can have a dielectric constant less than approximately 3.9. In one implementation, gap dielectrics in gaps 240 and/or 242 can comprise air, which has a dielectric constant of approximately 1.0.

In other implementations gap dielectrics in gaps 240 and/or 242 can comprise a low-k dielectric. As used herein, a low-k dielectric is a low dielectric constant material other than air. In various implementations, a low-k dielectric comprises carbon-doped silicon oxide, porous silicon oxide, porous carbon-doped silicon oxide, fluorinated amorphous carbon, aromatic hydrocarbon, parylene, silsesquioxane, or fluorinated silicon dioxide. In various implementations, a low-k dielectric has a dielectric constant from approximately 2.0 to approximately 3.0. In one implementation, a low-k dielectric can be used in addition to air in gaps 240 and/or 242. In one implementation, multiple and different low-k dielectrics can be situated in gaps 240 and/or 242.

Gaps 240 and 242 reduce capacitance between gate 220 and drains 216. In particular, gaps 240 greatly reduce capacitance between main portions of gate fingers 238 over active region 232 and drain contacts 217. Meanwhile gaps 242 greatly reduce capacitive coupling to drain contacts 217 from gate contacts 221, gate contact pads 236, and terminal portions of gate fingers 238 over isolation area 234.

In the present implementation, gaps 240 over active area 232 are continuous with gaps 242 over isolation area 234. In various implementations, gaps 240 can be distinct from gaps 242. For example, gaps 240 can be separated from gaps 242 by a portion of pre-metal dielectric. As another example, gaps 240 can comprise air while gaps 242 comprise a solid low-k dielectric layer, or vice versa, in order to balance reduction of capacitive coupling with structural stability.

Gaps 242 also reduce capacitive coupling to source contacts 219 from gate contacts 221, gate contact pads 236, and terminal portions of gate fingers 238. Referring back to FIG. 1B, capacitance between gate 120 and source 118 in lower transistor 114 may be less influential in amplifier applications. Accordingly, referring again to FIG. 2A, in one implementation, gaps 242 may be situated between gate contact pads 236 and drain contacts 217, but not between gate contact pads 236 and source contacts 219, in order to balance reduction in Miller capacitance with gap size and structural stability. In such implementation, pre-metal dielectric (instead of gaps 242) may be situated over isolation area 234 between sources 218 and the nearest portions of gate contact pads 236, as well as over terminal portions of gate fingers 238.

In the present implementation, although each drain contact 217 has two nearest gate fingers 238 (one on either side), gaps 240 are only situated between drain contacts 217 and one nearest gate finger 238 on one side. Such configuration can balance reduction in Miller capacitance with gap spacing and structural stability. In other implementations, gaps 240 can be situated on both sides of drain contacts 217 between both nearest gate fingers 238.

FIG. 2B illustrates a cross-sectional view of a portion of transistor 214 in FIG. 2A according to one implementation of the present application. FIG. 2B represents a cross-section along line “B-B” in FIG. 2A. As shown in FIG. 2B, transistor 214 includes handle wafer 244, buried oxide (BOX) 246, device layer 248, body 249, drain 216, source 218, gate oxide 250, gate finger 238, spacers 252, contact etch stop layer (CESL) 254, pre-metal dielectric (PMD) 256, drain contact 217, source contact 119, interlayer dielectrics (ILDs) 258 and 268, gap 240, metal interconnects 260, 262, 270, and 272, interconnect etch stop layer 264, and capping layer 266. Drain 216, source 218, gate finger 238, pre-metal dielectric (PMD) 256, drain contact 217, source contact 119, and gap 240 in FIG. 2B generally correspond to those features in FIG. 2A. Various features in FIG. 2B, such as CESL 254, spacers 252, and layers above PMD 256 were omitted or seen-through in FIG. 2A for simplicity.

Handle wafer 244, BOX 246, and device layer 248 can be provided together as a pre-fabricated semiconductor-on-insulator (SOI) wafer. In various implementations, a bonded and etch back SOI (BESOI) process, a separation by implantation of oxygen (SIMOX) process, or a “smart cut” process can be used for fabricating the SOI wafer as known in the art. In various implementations, handle wafer 244 can be silicon, high-resistivity silicon, germanium, or group III-V material. For example, handle wafer 244 can be monocrystalline bulk silicon. BOX 246 is situated on handle wafer 244. BOX 246 can be silicon dioxide or another oxide. In one implementation, a trap rich layer (not shown) can be situated under BOX 246.

Device layer 248 is situated on BOX 246. Device layer 248 can include any semiconductor material. For example, device layer 248 can be epitaxial silicon. Device layer 248 includes active area 232 shown in FIG. 2A, including drain 216, source 218, and body 249 that is under gate finger 238. In one implementation, transistor 214 is an NFET, drain 216 and source 216 are doped with an n-type dopant. Drain 216 and/or source 216 can include lightly-doped regions near gate finger 238. Drain 216 and/or source 216 can also include a silicide thereover (not shown). In the present implementation, drain 216 and source 216 are shown to reach the bottom of device layer 248. In other implementations, device layer 248 may be deeper, and a body well and body contact area can be utilized.

Gate oxide 250 is thin oxide situated over device layer 248 and between drain 216 and source 218. In one implementation, gate oxide 250 is silicon dioxide. Gate finger 238 is situated over gate oxide 250. In one implementation, gate finger 238 is polysilicon. transistor 214 can include gate contacts in another plane not visible in the cross-sectional view of FIG. 2B. Spacers 252 are formed on sides of gate finger 238. Spacers 252 can comprise, for example, silicon nitride (Si_{X}N_{Y}). Spacers 252 can be formed, for example, by a conformal chemical vapor deposition (CVD) followed by removal of select portions over and between gate fingers 238. As a result, spacers 252 can be situated on sides of gate fingers 238, separating gate fingers 238 from sources 216 and drains 218.

CESL 254 is situated over drain 218, source 218, and gate finger 238. In one implementation, CESL 254 comprises Si_{X}N_{Y}. In another implementation, CESL 254 is a bi-layer that comprises oxide and nitride, such as SiO₂ under Si_{X}N_{Y}. CESL 254 can be provided, for example, by plasma enhanced CVD (PECVD) or high density plasma CVD (HDP-CVD).

PMD 256 is situated over CESL 254. In various implementations, PMD 256 can comprise borophosphosilicate glass (BPSG), tetra-ethyl ortho-silicate (TEOS), silicon onynitride (SiO_{X}N_{Y}), silicon dioxide (SiO₂), silicon nitride (Si_{X}N_{Y}), or another dielectric. In one implementation, the dielectric constant of PMD 256 is approximately 3.9 or greater. Drain contact 217 and source contact 219 are situated in PMD 256. Drain contact 217 and source contact 219 extend through PMD 256 and CESL 254 to drain 216 and source 218 respectively. In one implementation, drain contact 217 and source contact 219 comprise tungsten (W). In one implementation, metal liners (not shown) can be situated under drain contact 217 and source contact 219. As described above, drains 216 are longer than sources 218. As a result, first distance D1 from gate finger 238 to its nearest source contact 219 is significantly less than second distance D2 from the gate finger 238 to its nearest drain contact 217.

ILD 258 is situated over PMD 256, drain contact 217, and source contact 219. Metal interconnects 260 and 262 are situated in ILD 258. Interconnect etch stop layer 264, capping layer 266, and ILD 268 are situated over ILD 258 and metal interconnects 260 and 262. Metal interconnects 270 and 272 are situated in ILD 268. ILDs 258 and 268, interconnect etch stop layer 264, and metal interconnects 260, 262, 270, and 272 represent a conventional back-end-of-line (BEOL) multi-level metallization (MLM) scheme. For example, metal interconnects 260, 262, 270, and 272 can be used for routing electrical signals between various devices (not shown in FIG. 2B) and drain contact 217 and source contact 119. ILDs 258 and 268, interconnect etch stop layer 264, and metal interconnects 260, 262, 270, and 272 can have predetermined thicknesses and spacing standardized by a manufacturer for use across multiple device designs. In the present implementation metal interconnects 260 and 262 are the first metal interconnect layer (i.e., M1) and metal interconnects 270 and 272 are the second metal interconnect layer (i.e., M2) respectively. In various implementations, metal interconnects 260, 262, 270, and 272 may comprise tungsten (W), copper (Cu), and/or aluminum (Al). Metal interconnects 260, 262, 270, and 272 may be formed by subtractive etch, single damascene, dual damascene, or any other suitable processes. Interconnect etch stop layer 264 serves as an etch stop for metal interconnects 270 and 272 to connect to metal interconnects 260 and 262. In one implementation, interconnect etch stop layer 264 comprises silicon carbide (SiC). ILDs 258 and 268 provide insulation between metal interconnect layers. In various implementations, ILDs 258 and 268 can comprise SiO_{X}N_{Y}, SiO₂, or Si_{X}N_{Y}.

Gap 240 is situated in PMD 256, as well as in ILD 258 and interconnect etch stop layer 264. Gap 240 may be formed after forming M1 and interconnect etch stop layer 264. For example, an opening can be formed in interconnect etch stop layer 264 to define the profile of gap 240. Then a hole can be etched in ILD 258 and PMD 256 to form gap 240. CESL 254 can serve as an etch stop for the hole, such that a bottom of gap 240 extends to CESL 254. Forming gap 240 can utilize the same etch chemistry utilized to form holes for drain contact 217 and source contact 219, except excluding the step that would break through CESL 254. For example, forming gap 240 can utilize a dry plasma etch using CH₄.

At least one gap dielectric is situated in gap 240. At least one gap dielectric has a dielectric constant less than that of PMD 256. Where PMD 256 comprises a multilayer, at least one gap dielectric has a dielectric constant less than that of at least one layer of PMD 256. Preferably, each gap dielectric in gap 240 has a dielectric constant less than that of any layer of PMD 256. Similarly, the gap dielectric can have a dielectric constant less than that of ILD 258. In one implementation, a low-k gap dielectric may be inserted in gap 240. Alternatively or additionally, air in gap 240 may serve as the gap dielectric. If gap 240 includes solid gap dielectric, it can be planarized, and then processing of transistor 214 can proceed in a conventional manner. Alternatively, if gap 240 includes a gaseous gap dielectric, capping layer 266 can be formed over gap 240, as well as over interconnect etch stop layer 264, to seal gap 240. Capping layer 266 can comprise a non-conformal oxide film. After forming capping layer 266, processing of transistor 214 can proceed in a conventional manner. The top of gap 240 shown in FIG. 2B is above drain contact 217 and metal interconnect 260. Gap 240 can have different height and/or width than shown in FIG. 2B. The dimensions of gap 240 can interrelate with the ability of capping layer 266 to successfully seal gap 240 (rather than being deposited at the bottom of gap 240).

Gap 240 is offset from gate finger 238 towards drain contact 217. In the present application, gap 240 being offset from gate finger 238 refers to the center of gap 240 not being approximately aligned with the center of gate finger 238. In the present implementation the center of gap 240 is over drain 216, and no portion of gap 240 overlies gate finger 238 or spacers 252. In various implementations, the center of gap 240 can be over spacer 252 or over an edge portion of gate finger 238, while still being offset from gate finger 238. In various implementations, the center of gap 240 is over drain 216 and outer portions of gap 240 overlie gate finger 238 or spacers 252. In one implementation, gap 240 may be positioned such that it does not extend beyond the edge of gate finger 238 nearest source contact 219. Gap 240 being offset from gate finger 238 towards drain contact 217 tends to introduce higher volume of gap dielectric (instead of PMD 256 or ILD 258) in paths between drain contact 217 or metal interconnect 260 and gate finger 238, reducing capacitance therebetween.

FIG. 2C illustrates a cross-sectional view of a portion of transistor 214 in FIG. 2A according to one implementation of the present application. FIG. 2C represents a cross-section along line “C-C” in FIG. 2A. As shown in FIG. 2C, transistor 214 includes handle wafer 244, BOX 246, device layer 248, active area 232, drain 216, isolation area 234, isolation 274, gate oxide 250, gate contact pad 236, spacer 252, CESL 254, PMD 256, drain contact 217, gate contact 221, ILDs 258 and 268, gap 242, metal interconnects 260, 262, 276, and 278, interconnect etch stop layer 264, and capping layer 266. Handle wafer 244, BOX 246, device layer 248, active area 232, drain 216, isolation area 234, gate oxide 250, gate contact pad 236, spacer 252, CESL 254, PMD 256, drain contact 217, gate contact 221, ILDs 258 and 268, gap 242, metal interconnects 260, 262, 276, and 278, interconnect etch stop layer 264, and capping layer 266 in FIG. 2C generally correspond to those features in FIGS. 2A and 2B.

Gate contact 221 is situated in PMD 256 over contact gate contact pad 236. Gate contact 221 extends through PMD 256 and CESL 254 to contact gate contact pad 236. In one implementation, gate contact 221 comprises W. In one implementation, metal liners (not shown) can be situated under gate contact 221. Metal interconnects 276 and 278 can be used for routing electrical signals between various devices (not shown in FIG. 2C) and gate contact 221. Otherwise, metal interconnect 276 may be similar to metal interconnect 260 in M1, and metal interconnect 278 may be similar to metal interconnect 270 in M2.

Gap 242 is situated outside of active area 232 over isolation area 234. In particular, gap 242 is situated over isolation area 234, between gate contact pad 236 and drain contact 217. Isolation area 234 includes isolation 274, which can comprise STI, LOCOS, or any other isolation technique.

Gap 242 in FIG. 2C can be formed in substantially the same manner as gap 240 in FIG. 2B. Gap 242 is situated in PMD 256, ILD 258, and interconnect etch stop layer 264. At least one gap dielectric is situated in gap 242 and has a dielectric constant less than that of PMD 256 and/or ILD 258. The bottom of gap 242 extends to CESL 254. Capping layer 266 can seal gap 242, and can be the same capping layer 266 over gap 240 in FIG. 2B. In other implementations, a capping layer utilized to seal gap 240 may be different from a capping layer utilized to seal gap 242, for example, if the width of gaps 240 and 242 are significantly different. The top of gap 242 shown in FIG. 2C is above drain contact 217 and metal interconnect 260, as well as gate contact pad 236, gate contact 221, and metal interconnect 276. Gap 242 tends to introduce higher volume of gap dielectric (instead of PMD 256 or ILD 258) in paths between drain contact 217 or metal interconnect 260 and gate contact pad 236, gate contact 221, or metal interconnect 276, reducing capacitance therebetween.

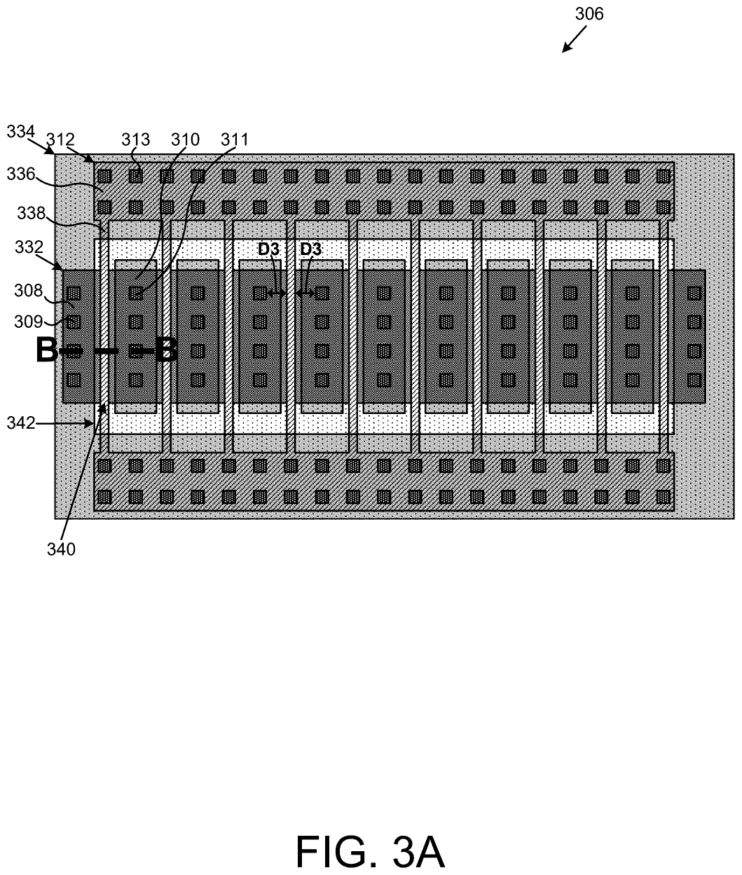

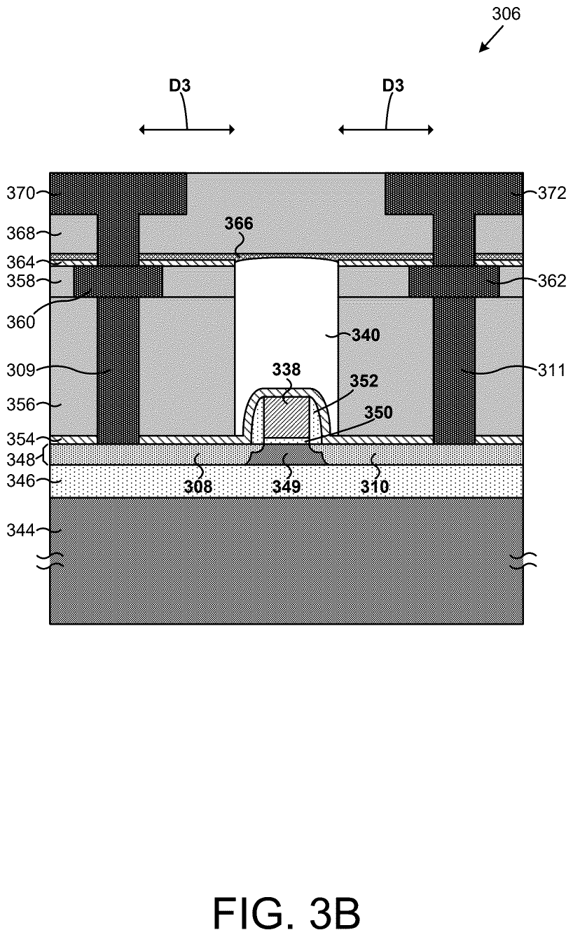

FIG. 3A illustrates a top view of a portion of a transistor according to one implementation of the present application. As shown in FIG. 3A, transistor 306 includes drains 308, drain contacts 309, sources 310, source contacts 311, gate 312, gate contact pads 336, gate fingers 338, gate contacts 313, active area 332, isolation area 334, gaps 340, and gaps 342. Transistor 306, drains 308, sources 310, and gate 312 in FIG. 3A generally correspond to transistor 106, drain 108, source 110, and gate 112 in FIG. 1B. In other words, transistor 306 in FIG. 3A can be the upper transistor 106 of the cascode in amplifier circuit 110b in FIG. 1B. Transistor 306 in FIG. 3A can be integrated on the same die as transistor 214 in FIG. 2A. Drains 216 in FIG. 2A can be coupled to sources 310 in FIG. 3A to couple the transistor in a cascode, as shown by transistors 106 and 114 in FIG. 1B. Certain features in transistor 306 in FIG. 3A may be omitted or seen-through for simplicity. Except for differences noted below, transistor 306 in FIG. 3A is generally similar to transistor 214 in FIG. 2A, and may have any implementations and advantages described above.

Notably, in transistor 306, drains 308 and sources 310 are symmetrical with respect to gate fingers 338. Drains 308 and sources 310 are approximately the same length. Gate fingers 338 are evenly spaced. Drain contacts 309 and source contacts 311 are approximately the same distance from gate fingers 238. That is, a distance from a gate finger 238 to its nearest source contact 311 and a distance from the gate finger to its nearest drain contact 309 are approximately the same distance D3.

In transistor 214 in FIG. 2A, gaps 240 over active area 232 were offset from gate fingers 238 towards drain contacts 217, and every other pair of drain contact 217 and source contact 219 had a gap 240 therebetween. In contrast, in transistor 306 in FIG. 3A, gaps 340 over active area 332 are approximately centered over gate fingers 338, and each pair of drain contact 309 and source contact 311 has a gap 340 therebetween.

FIG. 3B illustrates a cross-sectional view of a portion of transistor 306 in FIG. 3A according to one implementation of the present application.

FIG. 3B represents a cross-section along line “B-B” in FIG. 3A. As shown in FIG. 3B, transistor 306 includes handle wafer 344, BOX 346, device layer 348, body 349, drain 308, source 310, gate oxide 350, gate finger 338, spacers 352, CESL 354, PMD 356, drain contact 309, source contact 311, ILDs 358 and 368, gap 340, metal interconnects 360, 362, 370, and 372, interconnect etch stop layer 364, and capping layer 366. Drain 308, source 310, gate finger 338, PMD 356, drain contact 309, source contact 311, and gap 340 in FIG. 3B generally correspond to those features in FIG. 3A. Various features in FIG. 3B, such as CESL 354, spacers 352, and layers above PMD 356 were omitted or seen-through in FIG. 3A for simplicity. Except for differences noted below, transistor 306 in FIG. 3B is generally similar to transistor 214 in FIG. 2B, and may have any implementations and advantages described above. Similar layers may be shared by both transistors for ease of integration.

As described above, drains 308 and sources 310 are approximately the same length, and are symmetrical with respect to gate finger 338. Drain contact 309 and source contact 311 are approximately the same distance D3 from gate finger 238. Gap 340 is approximately centered over gate finger. That is, the center of gap 340 is approximately aligned with the center of gate finger 338. Gap 340 is approximately centered between drain contact 309 and source contact 311. Gap 340 tends to introduce higher volume of gap dielectric (instead of PMD 356 or ILD 358) in paths between drain contact 309 or metal interconnect 360 and source contact 311 or metal interconnect 362, reducing capacitance therebetween. Gap 340 also lightly reduces capacitance between drain contact 309 or metal interconnect 360 and gate finger 338, as well as between gate finger 338 and source contact 311 or metal interconnect 362.

Gap 340 can have different dimensions than shown in FIG. 3B. For example, in one implementation it may be desirable not to have a large gap 340 situated over gate finger 338, and instead utilize two smaller gaps, one gap between gate finger 338 and source contact 311 (e.g., over source 310) and another gap between gate finger 338 and drain contact 309 (e.g., over drain 308), in order to reduce capacitance between source contact 311 and drain contact 309. In another implementation, it may be desirable to have more capacitance reduction between source contact 311 and gate finger 338 of transistor 306, rather than between source contact 311 and drain contact 309. In such implementation, transistor 306 in FIGS. 3A-3B may be implemented as an inverse of transistor 214 in FIGS. 2A-2B. That is, transistor 306 in FIGS. 3A-3B may instead have sources 310 longer than drains 308, gate fingers 338 situated further from source contacts 311, and gaps 340 offset from gate fingers 340 towards source contacts 311.

Amplifiers according to the present invention are able to provide several advantages. First, referring to FIGS. 2A, 2B and 2C, since gate contacts 221 are not over active area 232 they have reduced capacitive coupling with drain contacts 217 and source contacts 219 over active area 232. Second, gaps 242 over isolation area 234 reduce capacitive coupling to drain contacts 217 and source contacts 219 from gate contacts 221, gate contact pads 236, and terminal portions of gate fingers 238. Third, since gate fingers 338 are spaced further from drain contacts 217, they have reduced capacitive coupling with drain contacts 217. Fourth, gaps 240 over active area 232 reduce capacitive coupling to drain contacts 217 from gate fingers 238.

Fifth, since the strongest capacitive coupling tends to occur with contacts and metal interconnects at M1, gaps 240 and 242 situated at and/or above these levels in PMD 256 and ILD 258 reduce capacitance where the reduction is most influential. Sixth, transistor 214 having a low number of gate fingers 338, for example, less than twenty, allows for easier biasing as well as for simple designs of gaps 240 and 242 with sufficient structural stability. Thus, when transistor 214 in FIGS. 2A, 2B and 2C is utilized as the lower transistor 114 of amplifier circuit 100b in FIG. 1B, lower transistor 114 has greatly reduced capacitance between gate 120 (which is coupled to input 102) and drain 116.

Seventh, referring to FIGS. 3A and 3B, various similar features reduce capacitances in transistor 306. Particularly, gaps 340 over active area 332 approximately centered over gate fingers 338 reduce capacitive coupling between drain contacts 309 and source contacts 311. Thus, when transistor 306 in FIGS. 3A and 3B is utilized as the upper transistor 106 of amplifier circuit 100b in FIG. 1B, upper transistor 106 has greatly reduced capacitance between source 110 and drain 108 (which is coupled to output 104). Eighth, when transistor 214 in FIGS. 2A, 2B and 2C and transistor 306 in FIGS. 3A and 3B are both utilized in combination as the cascode shown in FIG. 1B, the combination reduces capacitance from gate 120 to drain 116 of transistor 114, as well as from source 110 to drain 108 of transistor 106. That is, the combination reduces capacitance along the route from input 102 to output 104 in amplifier circuit 100b, strongly counteracting Miller effects, making amplifier circuit 100b particularly suited for radio frequency (RF) applications. Ninth, when implemented as SOI transistor structures, the inventive transistor structures provide lower parasitics, lower gate resistance, and reduced body effects compared to conventional transistors. Accordingly, SOI transistor structures according to the present application are particularly suited for use in amplifier circuit 100b.

Thus, various implementations of the present application achieve reduced capacitance utilizing the transistors of the present application and novel combinations to overcome the deficiencies in the art. From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the scope of those concepts. As such, the described implementations are to be considered in all respects as illustrative and not restrictive. It should also be understood that the present application is not limited to the particular implementations described above, but many rearrangements, modifications, and substitutions are possible without departing from the scope of the present disclosure.

1. A transistor comprising:
a drain, a source, and a gate;
a drain contact in a pre-metal dielectric, said pre-metal dielectric having a first dielectric constant;
a gap in said pre-metal dielectric, said gap over an active area and offset from said gate towards said drain contact;
a gap dielectric in said gap, said gap dielectric having a second dielectric constant less than said first dielectric constant so as to reduce a capacitance between said gate and said drain contact.

2. The transistor of claim 1, wherein said gap dielectric comprises air.

3. The transistor of claim 1, wherein said gap dielectric comprises a low-k dielectric.

4. The transistor of claim 1, wherein a first distance from said gate to a source contact is less than a second distance from said gate to said drain contact, so as to further reduce said capacitance between said gate and said drain contact.

5. The transistor of claim 1, wherein said gap is situated between a gate finger of said gate and said drain contact.

6. The transistor of claim 1, further comprising:
a contact etch stop layer under said pre-metal dielectric;
wherein a bottom of said gap extends to said contact etch stop layer.

7. A transistor comprising:
a drain, a source, and a gate;
a drain contact in a pre-metal dielectric, said pre-metal dielectric having a first dielectric constant;
a first gap in said pre-metal dielectric, said first gap over an isolation area and between said gate and said drain contact;
a first gap dielectric in said first gap, said first gap dielectric having a second dielectric constant less than said first dielectric constant so as to reduce a capacitance between said gate and said drain contact.

8. The transistor of claim 7, wherein said first gap dielectric comprises air.

9. The transistor of claim 7, wherein said first gap dielectric comprises a low-k dielectric.

10. The transistor of claim 7, further comprising:
a second gap in said pre-metal dielectric, said second gap over an active area and offset from said gate towards said drain contact;
a second gap dielectric in said second gap, said second gap dielectric having a third dielectric constant less than said first dielectric constant.

11. The transistor of claim 10, wherein said first gap and said second gap are continuous.

12. The transistor of claim 7, wherein a first distance from said gate to a source contact is less than a second distance from said gate to said drain contact, so as to further reduce said capacitance between said gate and said drain contact.

13. The transistor of claim 7, wherein said first gap is situated between a gate contact pad of said gate and said drain contact.

14. The transistor of claim 7, further comprising:
a contact etch stop layer under said pre-metal dielectric;
wherein a bottom of said first gap extends to said contact etch stop layer.

15. A semiconductor structure comprising:
a first transistor coupled to a second transistor;
said first transistor comprising:
a first drain contact and a first source contact in a pre-metal dielectric, said pre-metal dielectric having a first dielectric constant;
a first gap in said pre-metal dielectric, said first gap over a first active area and offset from a first gate towards said first drain contact;
a first gap dielectric in said first gap, said first gap dielectric having a second dielectric constant less than said first dielectric constant;
said second transistor comprising:
a second gap in said pre-metal dielectric, said second gap between a second drain contact and a second source contact;
a second gap dielectric in said second gap, said second gap dielectric having a third dielectric constant less than said first dielectric constant.

16. The semiconductor structure of claim 15, wherein at least one of said first gap dielectric and said second gap dielectric comprises air.

17. The semiconductor structure of claim 15, wherein said first transistor and said second transistor are utilized in an amplifier.

18. The semiconductor structure of claim 15, wherein said first transistor and said second transistor are coupled in a cascode, said first transistor is a lower transistor of said cascode, and said second transistor is an upper transistor of said cascode.

19. The semiconductor structure of claim 15, wherein said second gap is over a second active area and offset from a second gate towards said second source contact.

20. The semiconductor structure of claim 15, wherein said second gap is approximately centered over a gate finger of a second gate.
